(19) United States
(12) Patent Application Publication
(10) Pub. No.: US 2015/0101837 A1
(43) Pub. Date: Apr. 16, 2015

(54) ENCLOSURE FOR AN ELECTRICAL WIRE CONNECTION IN AN APPLIANCE

(71) Applicant: A. Raymond et Cie, Grenoble (FR)

(72) Inventors: Elio Evangelista, Chesterfield, MI (US); William Teller, Lake Orion, MI (US); Dorian Kilgore, Commerce Township, MI (US)

(73) Assignee: A. Raymond et Cie, Grenoble (FR)

(21) Appl. No.: 14/053,324

(22) Filed: Oct. 14, 2013

(51) Int. Cl. H05K 5/02; H05K 5/03

(52) U.S. Cl. CPC H05K 5/0247; H05K 5/0226; H05K 5/03
USPC 174/50; 29/428; 29/525; 29/525.01

(57) ABSTRACT

An enclosure for a wire connection includes a base and a cover. The base includes a bottom and a pair of longitudinal sidewalls disposed between the first and second ends. The cover includes a main body and a first wire securing member. According to one aspect, the cover further includes a second wire securing member. In another aspect, the first and second wire securing members are configured to engage first and second wires, respectively, to reduce strain on a connection between the first and second wires. In a further aspect, the first wire securing member is configured to engage the first wire to create a first bend in the first wire that extends into a first opening in the bottom of the base to reduce strain on the connection.

### BACKGROUND AND SUMMARY

The present invention relates to electrical wire connections, and more particularly, to enclosures for an electrical wire connection in an appliance.

In appliances such as washers, driers, refrigerators, freezers, ranges, and stoves, two or more wires are often joined together via an electrical splice. Traditionally, the splice is typically over-molded with polyvinyl chloride (PVC) cylinder or covered with heat shrink tape to electrically isolate the splice. However, either method of covering the splice is labor intensive and requires additional operations in the appliance assembly process which, in turn, increases the manufacturing cost of the appliance.

In accordance with the present invention, an enclosure for a wire connection in an appliance includes a base and a cover. The base includes a bottom and a pair of longitudinal sidewalls disposed between the first and second ends. The cover includes a main body and a first wire securing member. According to one aspect, the cover further includes a second wire securing member. In another aspect, the first and second wire securing members are configured to engage first and second wires, respectively, to reduce strain on a connection between the first and second wires. In a further aspect, the first wire securing member is configured to engage the first wire to create a first bend in the first wire that extends into a first opening in the bottom of the base to reduce strain on the connection.

The wire connection enclosure of the present invention is advantageous over traditional constructions. For example, the wire connection enclosure of the present invention reduces strain on wire connections by a greater magnitude relative to a PVC cylinder or heat shrink tape. In addition, the wire connection enclosure of the present invention is less expensive and requires less time to assemble relative to over-molding PVC or applying heat shrink tape. Further, the wire connection enclosure of the present invention enables appliance manufactures to save manufacturing costs associate with equipment such as molding machines, and to save floor space required for such equipment.

Additional advantages and features of the present invention will become apparent from the following description and appended claims, taken in conjunction with the accompanying drawings.

### BRIEF DESCRIPTION OF THE DRAWINGS

FIG. 1 is a perspective view showing an appliance of the present invention;

FIG. 2 is a perspective view showing wires in the appliance extending into an enclosure for a connection between the wires;

FIG. 3 is a perspective view showing the enclosure and the wires;

FIG. 4 is an exploded, top perspective view showing the enclosure and the wires;

FIG. 5 is a cross-sectional view, taken along line 5-5 of FIG. 3, showing the enclosure, the wires, and the connection between the wires;

FIG. 6 is a bottom perspective view showing a cover of the enclosure;

FIG. 7 is a bottom perspective view showing a base of the enclosure;

FIG. 8 is a cross-sectional view similar to FIG. 5 showing the enclosure with a push-in fastener extending from the base;

FIG. 9 is a cross-sectional view similar to FIG. 5 showing the enclosure with an edge-biter fastener extending from the base;

FIG. 10 is a cross-sectional view similar to FIG. 5 showing the enclosure with a zip tie loop extending from the base;

FIG. 11 is a top perspective view showing an alternative enclosure of the present invention in a closed position with wires extending into the alternative enclosure;

FIG. 12 is a first top perspective view showing the alternative enclosure in an open position, the wires, and the connection between the wires;

FIG. 13 is a second top perspective view showing the alternative enclosure in the open position;

FIG. 14 is a bottom perspective view showing the alternative enclosure in the open position;

FIG. 15 is a cross-sectional view, taken along line 15-15 of FIG. 11, showing the alternative enclosure, two of the wires, and the connection; and

FIG. 16 is a cross-sectional view, taken along line 16-16 of FIG. 11, showing the alternative enclosure and one of the wires.

Corresponding reference numerals indicate corresponding parts throughout the several views of the drawings.

### DETAILED DESCRIPTION

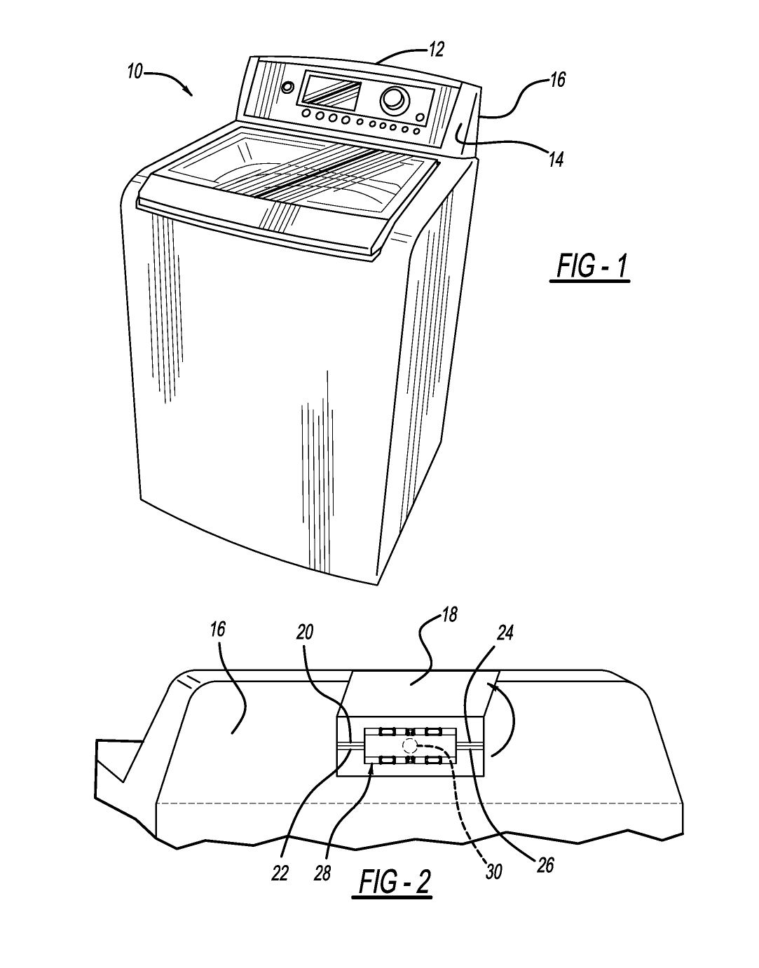

Referring to FIGS. 1 and 2, an appliance 10, such as a washer or a dryer, includes a control panel 12 having a front side 14 and a back side 16. The back side 16 of the control panel 12 includes a lid or door 18 that opens, as shown in FIG. 2, to provide access to various electrical components within the appliance 10. The electrical components include a first wire 20, a second wire 22, a third wire 24, a fourth wire 26, and an enclosure 28 for a connection 30 between the wires 20, 22, 24, 26, such as an electrical splice. The enclosure 28 covers and protects the connection 30 and exposed portions of the wires 20, 22, 24, 26 to electrically isolate the same and thereby prevent a short circuit. In addition, the enclosure 28 secures the wires to reduce the amount of strain on the connection 30.

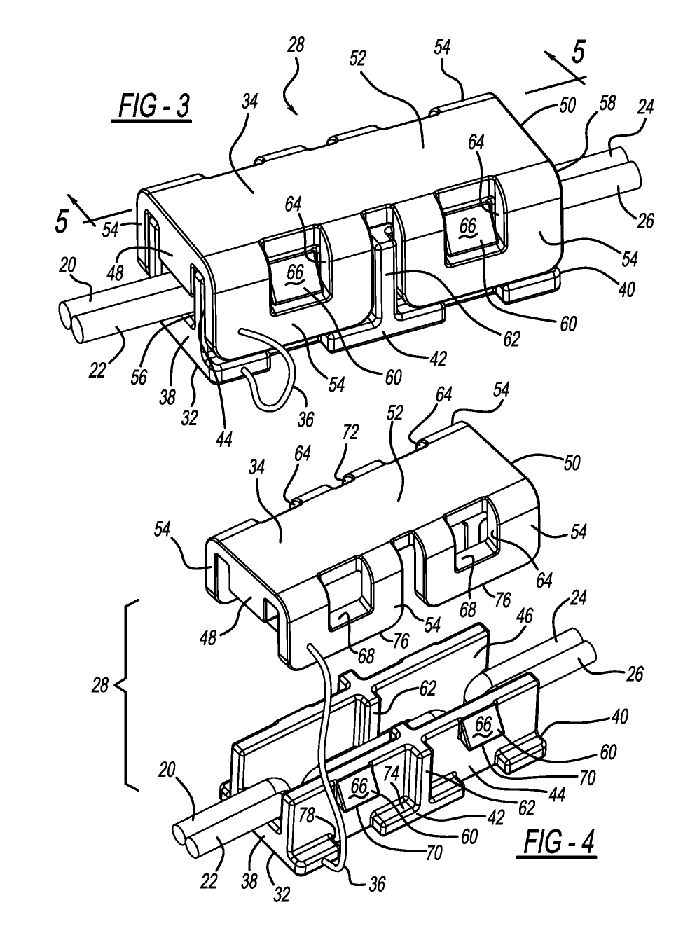

Referring to FIGS. 3 and 4, the enclosure 28 includes a base 32 and a cover 34. The base 32 and the cover 34 can be formed (e.g., molded) separately from a polymeric material (e.g., polyethylene, polypropylene). In various implementations, the enclosure 28 can include a tether 36 that couples the cover 34 to the base 32 to maintain the cover 34 with the base 32 for shipping and handling purposes. The base 32 has a first end 38 and a second end 40 and includes a bottom 42, a pair of longitudinal sidewalls 44, and an open top 46. The cover 34 has a first end 48 and a second end 50 and includes a rectangular cuboid main body 52 and two pairs of flexible brackets 54 extending from opposite longitudinal sides of the main body 52.

The flexible brackets 54 can be slid over the longitudinal sidewalls 44 of the base 32 to couple the cover 34 to the base 32 using a snap or interference fit. When the cover 34 is coupled to the base 32, the first end 38 of the base 32 and the first end 48 of the cover 34 cooperate to define a first open end 56 of the enclosure 28, which is shown receiving the wires 20, 22. In addition, the second end 40 of the base 32 and the second end 50 of the cover 34 cooperate to define a second open end 58 of the enclosure 28, which is shown receiving the wires 24, 26.

The base 32 further includes ramped protrusions 60 and lateral walls 62 intersecting the longitudinal sidewalls 44 at the longitudinal midpoint of the base 32, and the flexible brackets 54 of the cover 34 define openings 64 for receiving the ramped protrusions 60. As the flexible brackets 54 of the cover 34 are slid over the longitudinal sidewalls 44 of the base 32, the brackets 54 deflect outward due to engagement with sloped surfaces 66 on the ramped protrusions 60. Once inner surfaces 68 of the flexible brackets 54 are slid past underside surfaces 70 of the ramped protrusions 60, the brackets 54 return to their original state and the ramped protrusions 60 extend through the openings 64. In turn, the underside surfaces 70 of the ramped protrusions 60 engage the inner surfaces 68 of the flexible brackets 54 to retain the cover 34 onto the base 32.

The lateral walls 62 of the base 32 can be used to position the cover 34 relative to the base 32 before coupling the cover 34 to the base 32. For example, slots 72 between the flexible brackets 54 of the cover 34 can be aligned with the lateral walls 62. Then, as the flexible brackets 54 are slid over the longitudinal sidewalls 44 of the base 32, the lateral walls 62 can engage the slots 72 to guide the cover 34 until the ramped protrusions 60 extend through the openings 64. At that point, a top surface 74 on the bottom 42 of the base 32 can act as a stop by engaging an underside surface 76 of the flexible brackets 54 to ensure that height of the open ends 56, 58 is sufficient to receive the wires 20, 22, 24, 26. The bottom 42 of the base 32 define slots 78, which can provide access for a tool, such as a flathead screwdriver, to pry the flexible brackets 54 away from the longitudinal sidewalls 44 to remove the cover 34 from the base 32.

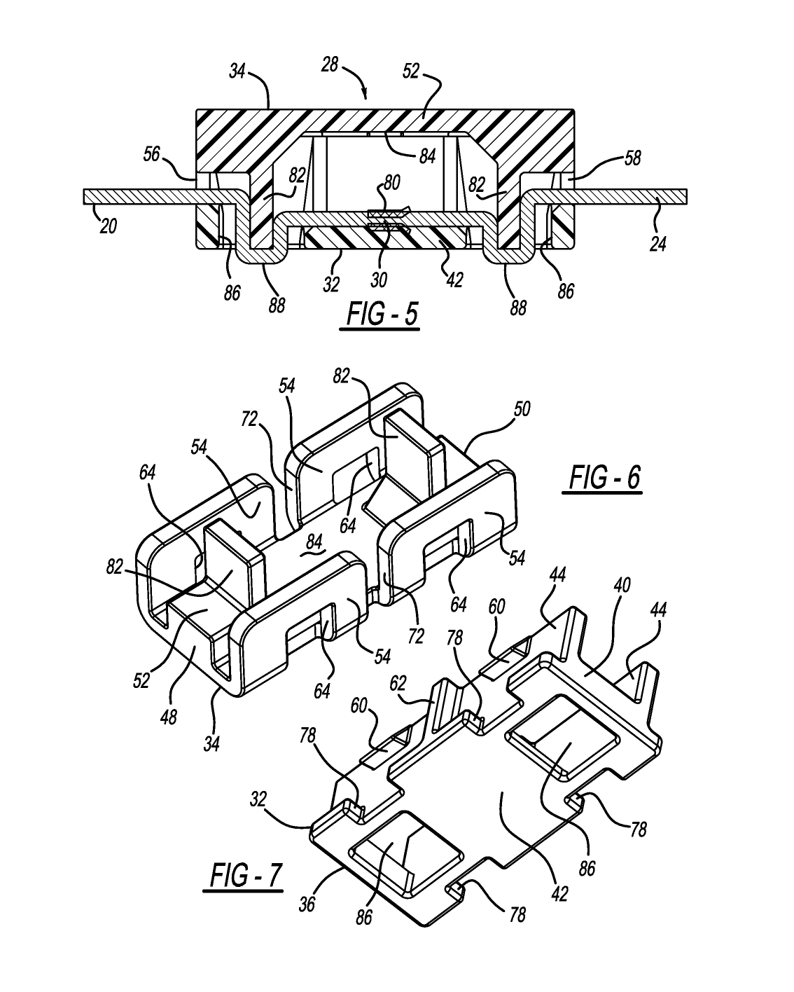

With additional reference to FIG. 5, before the cover 34 is coupled to the base 32, a crimp connector 80 can be placed over the connection 30 between the wires 20, 22, 24, 26 and crimped, and then the wires 20, 22, 24, 26 can be placed in the base 32. Although the connection 30 is a two-to-two connection (i.e., a connection between the two wires 22, 24 and the two wires 26, 28), the enclosure 28 can be used with other connections. For example, the enclosure 28 can be used with a two-to-one connection a three-to-one connection, a three-to-two connection, or a five-to-five connection. In addition, the enclosure can be used to connect wires having different gauges.

With additional reference to FIGS. 6 and 7, the cover 34 further includes wire securing members 82, such as rectangular tabs or standoffs, extending from an underside surface 84 of the main body 52, and the bottom 42 of the base 32 defines openings 86. One of the securing members 82 is located between the first end 50 of the cover 34 and the longitudinal midpoint of the cover 34, and the other one of the securing members 82 is located between the longitudinal midpoint of the cover 34 and the second end 50 of the cover 34. The securing members 82 cooperate with the openings 86 to secure the wires 20, 22, 24, 26 within the enclosure 28 and thereby reduce the amount of strain on the connection 30.

When the wires 20, 22, 24, 26 extend through the open ends 56, 58 of the enclosure 28 and the cover 34 is coupled to the base 32, the securing members 82 engage the wires 20, 22, 24, 26 the create bends 88 therein. The bends 88 in the wires 20, 22, 24, 26 are disposed on opposite sides of the connection 30 and extend into the openings 86 such that the wires 20, 22, 24, 26 are routed in a serpentine pattern as shown in FIG. 5. The engagement between the securing members 82 and the wires 20, 22, 24, 26 at the bends 88 prevents the wires 20, 22, 24, 26 from moving longitudinally and thereby reduces the amount of strain on the connection 30. In addition, the bottom 42 of the base 32 and the longitudinal walls 44 cooperate with the main body 52 of the cover 34 and the securing members 82 to enclose and thereby electrically isolate the connection 30 and exposed portions of the wires 20, 22, 24, 26 adjacent to the connection 30.

To quantify the amount by which the enclosure 28 reduces strain on a wire connection relative to an over-molded PVC cylinder, a pull-test was performed on a connection between two 18 gauge wires. When testing the over-molded PVC cylinder, the wires began to slide within the PVC cylinder when about 30 pounds (lbs) to 35 lbs (133 Newtons (N) to 156 N) of longitudinal force was applied to one of the wires. In contrast, when testing the enclosure 28, the wires did not begin to slide within the enclosure 28 until about 50 lbs (222 N) of longitudinal force was applied to one of the wires. Thus, the enclosure 28 yields an approximate 40% improvement in the longitudinal load capacity of the connection relative to the PVC cylinder. In addition, as indicated above, these test results are for a connection between two wires. The enclosure 48 may provide a higher degree of strain relief for a connection between more wires, which may further increase the longitudinal load capacity of the connection.

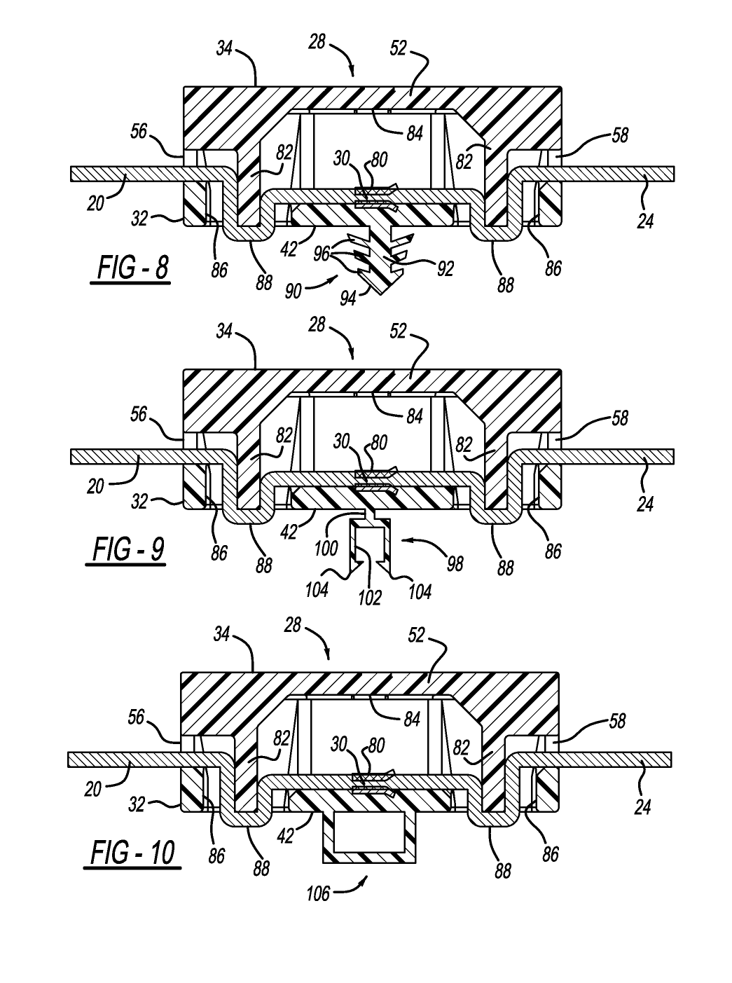

Referring to FIGS. 8 through 10, the enclosure 28 can include various mounting members for attaching the enclosure 28 to other components in the appliance 10. The mounting members can be formed integral with the base 32 or the cover 34 or formed separate from the base 32 and the cover 34 and attached to the base 32 or the cover 34. The mounting members can be formed (e.g., molded) from a polymeric material (e.g., polyethylene, polypropylene).

In one example, the enclosure 28 can include a push-in clip 90 extending from the bottom 42 of the base 32, as shown in FIG. 8, which may be referred to as a Christmas tree fastener. The push-in clip 90 includes a shank 92 having a conical distal end 94 and annular ribs 96 extending proximally from the shank 92. The push-in clip 90 can be inserted into a hole in a component in the appliance 10, such as a bracket, and the ribs 96 can engage a surface of the component surrounding the hole to fix the enclosure 28 to the component.

In a second example, the enclosure 28 can include an edge-biter fastener 98 extending from the bottom 42 of the base 32, as shown in FIG. 9. The edge-biter fastener 98 includes a shank 100 and a u-shaped channel 102 extending from the shank 100 and having barbed distal ends 104. The u-shaped channel 102 can be sized to receive an edge of a component in the appliance 10, such as a panel, and the distal ends 104 can pierce or bite into the component to fix the enclosure 28 to the component. In a third example, the enclosure 28 can include a zip tie loop 106 extending from the bottom 42 of the base 32, as shown in FIG. 10. A zip tie or cable tie can be inserted through the loop 106 to secure the enclosure 28 to a component in the appliance 10.

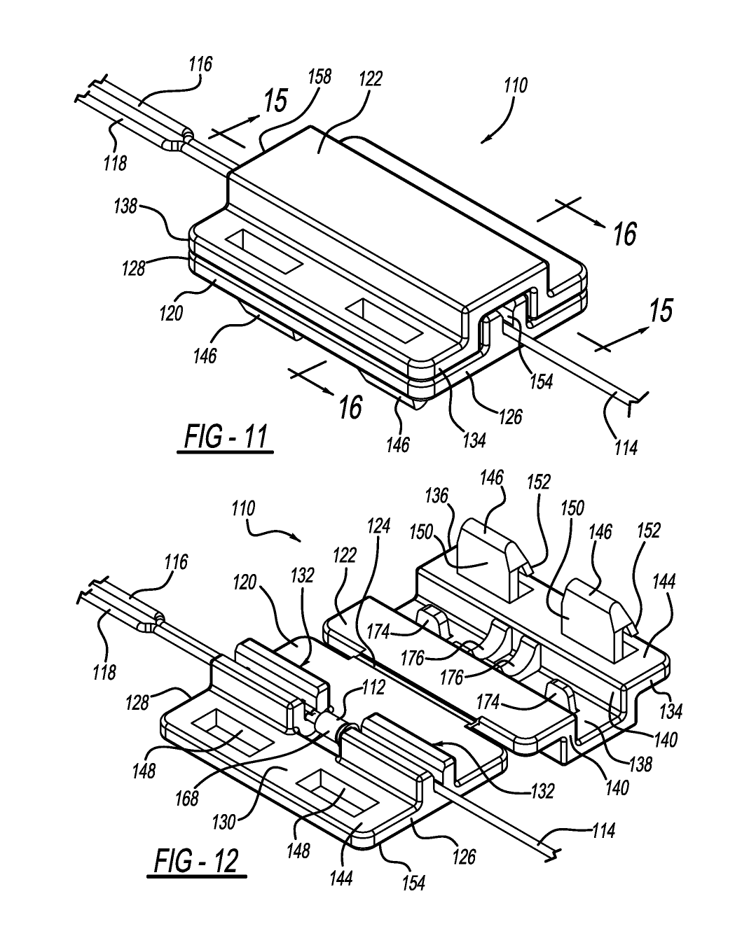

Referring to FIGS. 11 and 12, an enclosure 110 electrically isolates and provides a strain relief for a connection 112, such as a splice, between a first wire 114, a second wire 116, and a third wire 118. The enclosure 110 includes a base 120, a cover 122, and a hinge 124 attaching the cover 122 to the base 120. The base 120, the cover 122, and the hinge 124 can be integrally formed (e.g., molded) from plastic (e.g., polyethylene, polypropylene). In this regard, the hinge 124 can be a living hinge.

The base 120 has a first end 126 and a second end 128 and includes a flat rectangular bottom 130 and wire retaining members 132. The cover 122 has a first end 134 and a second end 136 and includes a rectangular main body 138, longitudinal sidewalls 140, platforms 144, and flexible brackets 146. The flexible brackets 146 extend through openings 148 in the bottom 130 of the base 120 when the cover 122 is rotated about the hinge 124 to close the enclosure 110, as shown in FIG. 11. The retaining members 132 of the base 120 retain or secure the wires 114, 116, 118 to the base 120 when the cover 122 is rotated about the hinge 124 to open the enclosure 110, as shown in FIG. 12.

The flexible brackets 146 include blades 150 and tabs 152 extending from the blades 150. The tabs 152 deflect toward the blades 150 as the flexible brackets 146 are inserted through the openings 148 in the cover 122. When the tabs 152 are inserted completely through the openings 148, the tabs 152 return to their original state and engage an underside surface 154 of the base 120 to keep the enclosure 110 closed. When the enclosure 110 is closed, the first end 126 of the base 120 and the first end 134 of the cover 122 cooperate to define a first open end 156 of the enclosure 110, which is shown receiving the first wire 114. In addition, the second end 128 of the base 120 and the second end 136 of the cover 122 cooperate to define a second open end 158 of the enclosure 110, which is shown receiving the second and third wires 116, 118.

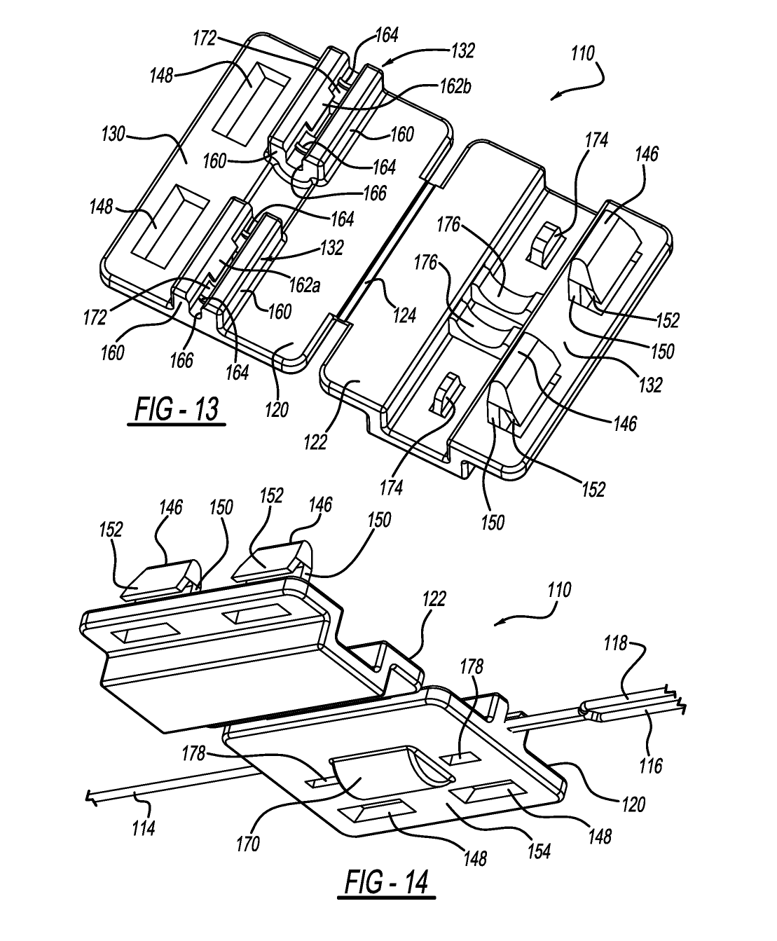

With additional reference to FIGS. 13 and 14, the retaining members 132 include longitudinal sidewalls 160, flexible tabs 162a, 162b, and annular ribs 164. The longitudinal sidewalls 160 form u-shaped channels 166, with one of the channels 166 receiving the first wire 114 and the other one of the channels 166 receiving the second and third wires 116, 118. A crimp connector 168 (FIG. 12) can be crimped onto the connection 112 before the wires 114, 116, 118 are placed in the u-shaped channels 166. The base 120 can further include a semicylinder pocket 170 (FIG. 14) extending from the underside surface 154 of the base 120 to provide clearance for the crimp connector 168.

After the connection 112 is formed, the wires 114, 116, 118 can be inserted through open tops 172 of the u-shaped channels 166. As the wires 114, 116, 118 are inserted through the open tops 172, the flexible tabs 162a, 162b deflect inward due to engagement with the wires 114, 116, 118. When the wires 114, 116, 118 are inserted past the flexible tabs 162a, 162b, the flexible tabs 162a, 162b return to their original state. The flexible tabs 162a, 162b can be sized based on the number and/or gauge of wires to be inserted into the u-shaped channels 166 to ensure that the wires can be inserted into the channels 166 and that the tabs 162a, 162b retain the wires. In this regard, the flexible tab 162a is slightly larger than the flexible tab 162b since the tab 162a retains only the first wire 114 while the tab 162b retains the second and third wires 116, 118.

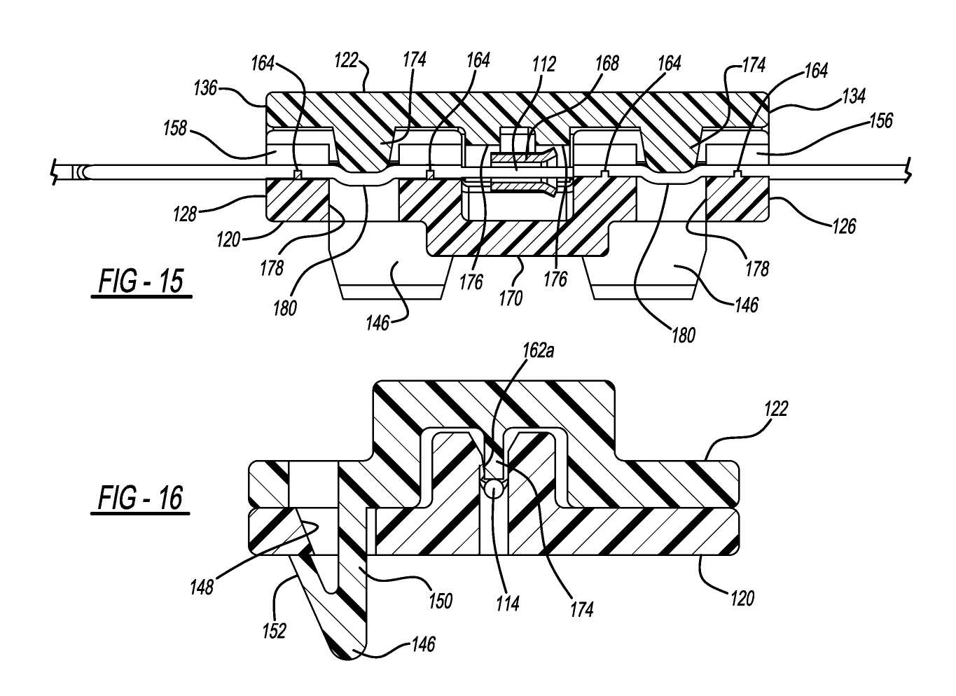

With additional reference to FIGS. 15 and 16, the cover 122 further includes wire securing members 174, such as rectangular tabs or standoffs, and c-shaped channels 176. In addition, the bottom 130 of the base 120 defines openings 178 disposed in the u-shaped channels 166. One of the securing members 174 is located between the first end 134 of the cover 122 and the longitudinal midpoint of the cover 122, and the other one of the securing members 174 is located between the longitudinal midpoint of the cover 122 and the second end 126 of the cover 122. The securing members 174 cooperate with the openings 178 to secure the wires 114, 116, 118 within the enclosure 110 and thereby reduce the amount of strain on the connection 112.

When the wires 114, 116, 118 are placed in the u-shaped channels 166 and the enclosure 110 is closed, the securing members 174 engage the wires 114, 116, 118 the create bends 180 therein. The bends 180 are disposed on opposite sides of the connection 112 and extend into the openings 178 in the base 120 such that the wires 114, 116, 118 are routed in a serpentine pattern as shown in FIG. 15. The engagement between the securing members 174 and the wires 114, 116, 118 at the bends 180 prevents the wires 114, 116, 118 from moving longitudinally and thereby reduces the amount of strain on the connection 112. In addition, the bottom 130 of the base 120 and the longitudinal walls 160 cooperate with the main body 138 of the cover 122 and the securing members 174 to enclose and thereby electrically isolate the connection 112 and exposed portions of the wires 114, 116, 118 adjacent to the connection 112.

In addition, when the enclosure 110 is closed, the flexible tabs 162a, 162b deflect inward due to engagement with the securing members 174. The flexibility of the tabs 162a, 162b allows the securing members 174 to be inserted into the u-shaped channels 166. Further, when the enclosure 110 is closed, the c-shaped channels 176 of the cover 122 at least partially surround the connection 112 and exposed portions of the wires 114, 116, 118 to protect the same. Moreover, when the wires 114, 116, 118 are placed in the u-shaped channels 166, the annular ribs 164 on the base 120 bite into the wires 114, 116, 118 to further secure the wires 114, 116, 118 to the base 120.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. An enclosure for a wire connection, comprising:
a base having a first end and a second end and including a bottom and a pair of longitudinal sidewalls disposed between the first and second ends; and
a cover having a first end and a second end and including a main body, a first wire securing member disposed between the first end of the cover and the longitudinal midpoint of the cover, and a second wire securing member disposed between the longitudinal midpoint of the cover and the second end of the cover, wherein the cover is configured to be coupled to the base, and, when the cover is coupled to the base:
the first end of the cover cooperates with the first end of the base to form a first open end configured to receive a first wire;
the second end of the cover cooperates with the second end of the base to form a second open end configured to receive a second wire; and
the first and second wire securing members of the cover are configured to engage the first and second wires, respectively, to reduce strain on a connection between the first and second wires.

2. The enclosure of claim 1, wherein the first and second wire securing members are configured to create bends in the first and second wires on opposite sides of the connection between the first and second wires.

3. The enclosure of claim 1, wherein the bottom of the base defines first and second openings, the first and second wire securing members of the cover cooperating with the first and second openings of the base to retain the first and second wires.

4. The enclosure of claim 3, wherein:
the first wire securing member of the cover and the first opening in the bottom of the base cooperate to create a first bend in the first wire that extends into the first opening in the base; and
the second wire securing member of the cover and the second opening in the bottom of the base cooperate to create a second bend in the second wire that extends into the second opening in the base.

5. The enclosure of claim 1, wherein the cover further includes flexible brackets extending from the main body and configured to overlap the longitudinal sidewalls of the base when the cover is coupled to the base.

6. The enclosure of claim 5, wherein each of the flexible brackets defines an opening configured to receive a protrusion disposed on the longitudinal sidewalls of the base to couple the cover to the base.

7. The enclosure of claim 6, wherein the protrusions on the longitudinal sidewalls are ramped protrusions having sloped surfaces.

8. The enclosure of claim 7, wherein the flexible brackets deflect outward due to engagement with the sloped surfaces on the ramped protrusions as the flexible brackets are slid over the longitudinal sidewalls of the base.

9. The enclosure of claim 1, wherein the enclosure is configured to reduce the strain on the connection between the first and second wires such that the connection has a longitudinal load capacity of at least about 220 Newtons.

10. The enclosure of claim 1, wherein the bottom of the base and the longitudinal sidewalls cooperate with the main body of the cover and the first and second wire securing members to enclose and thereby electrically isolate the connection and exposed portions of the first and second wires adjacent thereto.

11. The enclosure of claim 1, wherein each of the first and second wire securing members of the base includes a rectangular standoff oriented perpendicular to the longitudinal sidewalls of the base.

12. The enclosure of claim 1, wherein each of the first and second wire securing members of the base includes a rectangular standoff oriented parallel to the longitudinal sidewalls of the base.

13. The enclosure of claim 1, further comprising a hinge attaching the cover to the base, wherein the cover is rotatable about the hinge to close the enclosure.

14. The enclosure of claim 13, wherein the cover further includes a flexible bracket configured to extend through an opening in the base and engage an underside surface of the base to couple the cover to the base.

15. The enclosure of claim 13, wherein the hinge is a living hinge.

16. The enclosure of claim 1, wherein at least one of the first wire and the second wire includes multiple wires.

17. An enclosure for a wire connection, comprising:
a base having a first end and a second end and including a bottom and a pair of longitudinal sidewalls extending from the bottom and disposed between the first and second ends of the base, the bottom defining a first opening; and
a cover having a first end and a second end and including a main body and a first wire securing member extending from the main body, wherein the cover is configured to be coupled to the base, and, when the cover is coupled to the base:
the first end of the cover cooperates with the first end of the base to form a first open end configured to receive a first wire;
the second end of the cover cooperates with the second end of the base to form a second open end configured to receive a second wire; and
the first wire securing member of the cover is configured to engage the first wire to create a first bend in the first wire that extends into the first opening to reduce strain on a connection between the first and second wires.

18. The enclosure of claim 17, wherein the bottom of the base defines a second opening and the cover further includes a second wire securing member extending from the main body, the second wire securing member being configured to engage the second wire to create a second bend in the second wire that extends into the second opening in the bottom of the base.

19. The enclosure of claim 17, further comprising a tether that attaches the cover to the base.

20. The enclosure of claim 17, further comprising a push-in fastener extending from one of the base and the cover for securing the enclosure to a component within an appliance.

21. The enclosure of claim 17, further comprising an edge-biter fastener extending from one of the base and the cover for securing the enclosure to a component within an appliance.

22. The enclosure of claim 17, further comprising a zip tie loop extending from one of the base and the cover for securing the enclosure to a component within an appliance.

23. The enclosure of claim 17, wherein the base and the cover are formed separately from a polymeric material.

24. The enclosure of claim 17, further comprising a hinge attaching the cover to the base, wherein the base, the cover, and the hinge are integrally formed from a polymeric material, and the hinge is a living hinge.

25. The enclosure of claim 17, wherein at least one of the first wire and the second wire includes multiple wires.

26. A method of enclosing a connection between a first wire and a second wire and reducing strain on the connection, the method comprising:
placing the connection within a base of an enclosure such the first wire extends through a first end of the base and the second wire extends through a second end of the base; and
placing a cover of the enclosure on the base such that first and second wire securing members on the cover engage the first and second wires, respectively, to create bends in the first and second wires on opposite sides of the connection and thereby reduce the amount of strain on the connection.

27. The method of claim 26 further comprising positioning the connection at the longitudinal midpoint of the cover such that the first and second wire securing members are disposed on opposite sides of the connection when the cover is placed on the base.

28. The method of claim 26 further comprising coupling the cover to the base using a snap fit mechanism.

29. The method of claim 26 further comprising sliding at least one pair of opposing flexible brackets on the cover over longitudinal sidewalls of the base until projections on the base extend through openings in the flexible brackets to couple the cover to the base.

30. The method of claim 26 further comprising rotating the cover about a hinge between the base and the cover until flexible brackets on the cover extend through openings in the base and engage a underside surface of the base to couple the cover to the base.
